(19) United States
(12) Patent Application Publication
(10) Pub. No.: US 2006/0103416 A1
(43) Pub. Date: May 18, 2006

(54) Substrate inspecting method

(76) Inventors: Masaki Miyatake, Konosu-shi (JP); Mitsuhiro Yamamoto, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/294,549

(22) Filed: Dec. 6, 2005

Related U.S. Application Data
(63) Continuation of application No. PCT/JP04/07986, filed on Jun. 2, 2004.

(30) Foreign Application Priority Data
Jun. 6, 2003 (JP) 2003-162204

(51) Int. Cl. G01R 31/00

(52) U.S. Cl. 324/770

(57) ABSTRACT

A method of inspecting a substrate comprising forming the common terminal that is connected to a part of wirings formed in the first array region and a part of wirings formed in the second array region on the substrate, supplying an electric signal from the common terminal to both of the part of the wirings formed in the first array region and the part of the wirings formed in the second array region, thereby charging the pixel electrodes in the first and second array regions, and irradiating an electron beam to the charged pixel electrodes, and inspecting whether or not the pixel electrodes properly hold the electrical charge based on a data of a secondary electron emitted from the pixel electrodes.

### CROSS-REFERENCE TO RELATED APPLICATIONS

This is a Continuation Application of PCT Application No. PCT/JP2004/007986, filed Jun. 2, 2004, which was published under PCT Article 21(2) in Japanese.

This application is based upon and claims the benefit of priority from prior Japanese Patent Application No. 2003-162204, filed Jun. 6, 2003, the entire contents of which are incorporated herein by reference.

### BACKGROUND OF THE INVENTION

1. Field of the Invention

The present invention relates to a substrate inspecting method.

2. Description of the Related Art

Liquid crystal displays are used in various sections of devices such as a display unit of a notebook personal computer (notebook PC), a display unit of a mobile telephone and a display unit of a television set. A liquid crystal display includes an array substrate in which a plurality of pixel electrodes are arranged in matrix, an opposite substrate including opposite electrode that respectively face the plurality of pixel electrodes, and a liquid crystal layer held between the array substrate and opposite substrate.

The array substrate includes a plurality of pixel electrodes arranged in matrix, a plurality of scanning lines arranged respectively along with rows of the pixel electrodes, a plurality of signal lines arranged respectively along with columns of the pixel electrodes and a plurality of switching elements each arranged in a vicinity of a crossing position where each scanning line and each signal line intersect.

There are two types of array substrates, namely a array substrate in which its switching elements are thin film transistors each using an amorphous silicon semiconductor thin film and another array substrate in which its switching elements are thin film transistors each using a polysilicon semiconductor thin film. The carrier mobility of Polysilicon is higher than that of amorphous silicon. It should be noted here that the polysilicon type array substrate can contain not only switching elements for pixel electrodes, but also drive circuits for scanning lines and signal lines built in there.

Array substrates described above undergo an inspection step in their production process in order to inspect them for defects. Examples of the inspection method and inspection device are discussed in Jpn. Pat. Appln. KOKAI Publication No. 11-271177, Jpn. Pat. Appln. KOKAI Publication No. 2000-3142 and U.S. Pat. No. 5,268,638.

Jpn. Pat. Appln. KOKAI Publication No. 11-271177 discloses a technique of inspecting amorphous type LCD substrates, which involves a characteristic point defect inspection process. This technique is based on the following mechanism. That is, direct light of DC component is applied on an entire surface of an LCD substrate, and as the amorphous silicon film senses the light, it becomes conductive. Here, the states of defect can be judged by detecting the amount of leak of charge accumulated in the auxiliary capacitor. The technique disclosed in Jpn. Pat. Appln. KOKAI Publication No. 2000-3142 utilizes such mechanism that when an electron beam is irradiated on a pixel electrode, the amount of the secondary electron emitted is proportional to the voltage applied to the thin film transistor. The technique of U.S. Pat. No. 5,268,638, as well, utilizes the secondary electron emitted when an electron beam is irradiated on a pixel electrode.

The product price of a liquid crystal display is greatly dependent on the cost of the production facilities. The above-described inspection method is essential to the production facilities, and the revision and correction of the designing of the inspection device result in a great amount of expense.

The present invention has been proposed in the light of the above-described point, and the object thereof is to provide a method of inspecting a substrate, which can reduce the opportunities of revising and correcting the designing of the inspection device, thereby suppressing the increase in the product cost of the liquid crystal display.

### BRIEF SUMMARY OF THE INVENTION

In order to achieve the above-described object, there is provided, according to an aspect of the present invention, a method of inspecting a substrate which comprises a common terminal, and a first array region and a second array region each containing wirings including a plurality of scanning lines and a plurality of signal lines, a plurality of switching elements each formed in a vicinity of an intersection of the respective scanning line and the respective signal line and a plurality of pixel electrodes connected respective to the plurality of switching elements, the method comprising: forming the common terminal that is connected to a part of wirings formed in the first array region and a part of wirings formed in the second array region on the substrate; supplying an electric signal from the common terminal to both of the part of the wirings formed in the first array region and the part of the wirings formed in the second array region, thereby charging the pixel electrodes in the first and second array regions; and irradiating an electron beam to the charged pixel electrodes, and inspecting whether or not the pixel electrodes properly hold the electrical charge based on a data of a secondary electron emitted from the pixel electrodes.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view illustrating the connection relationship between a normal pad group and a connection pad group CPDp according to an embodiment of the present invention;

FIG. 2 is a diagram schematically showing a cross section of a liquid crystal display;

FIG. 3 is a perspective view of a part of the liquid crystal display shown in FIG. 2;

FIG. 4 is a plan view illustrating an example of an arrangement of array substrates constituted with use of a mother substrate;

FIG. 5 is a plan view schematically showing an array substrate;

FIG. 6 is an enlarged plan view schematically showing a part of a pixel region of the array substrate shown in FIG. 5;

FIG. 7 is a diagram schematically showing a cross section of a liquid crystal display comprising the array substrate shown in FIG. 6;

FIG. 8 is a structural diagram schematically showing an inspection apparatus for array substrates, which includes an electron beam tester;

FIG. 9 is a plan view illustrating a main portion of an array substrate portion;

FIG. 10 is a flowchart designed to illustrate the method of inspecting an array substrate; and

FIG. 11 is a plan view schematically showing a remodeled example of the array substrate.

### DETAILED DESCRIPTION OF THE INVENTION

A method of inspecting substrate according to an embodiment of the invention, will be described with reference to the drawings. First, a liquid crystal display including polysilicon type array substrates will be described.

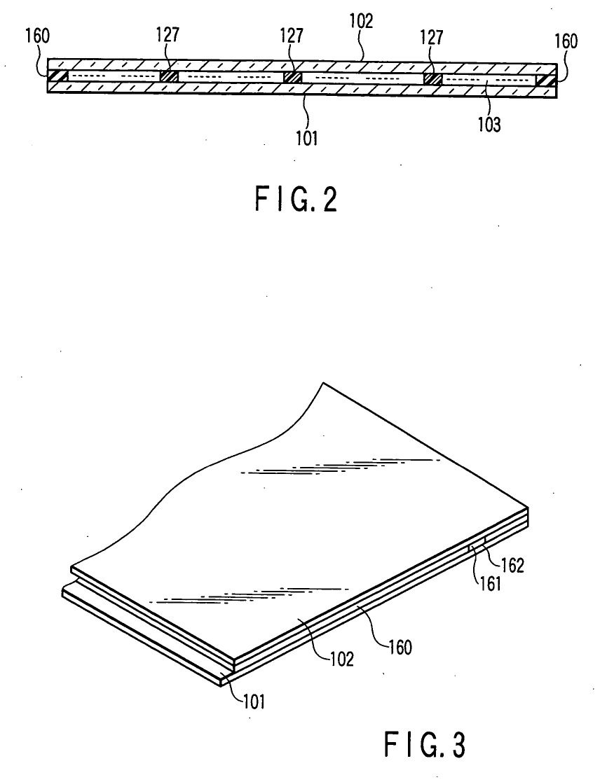

As shown in FIGS. 2 and 3, the liquid crystal display includes an array substrate 101a, an opposite substrate 102 arranged opposite to the array substrate 101a with a predetermined gap kept between them, and a liquid crystal layer 103 interposed between these substrates. The array substrate 101a and opposite substrate 102 have a predetermined gap kept between them by means of a columnar spacer 127 serving as a spacer. The peripheral portions of the array substrate 101a and opposite substrate 102 are bonded together with a sealing material 160. A liquid crystal inlet 161 that is formed in a part of the sealing material 160 is sealed with a sealant 162.

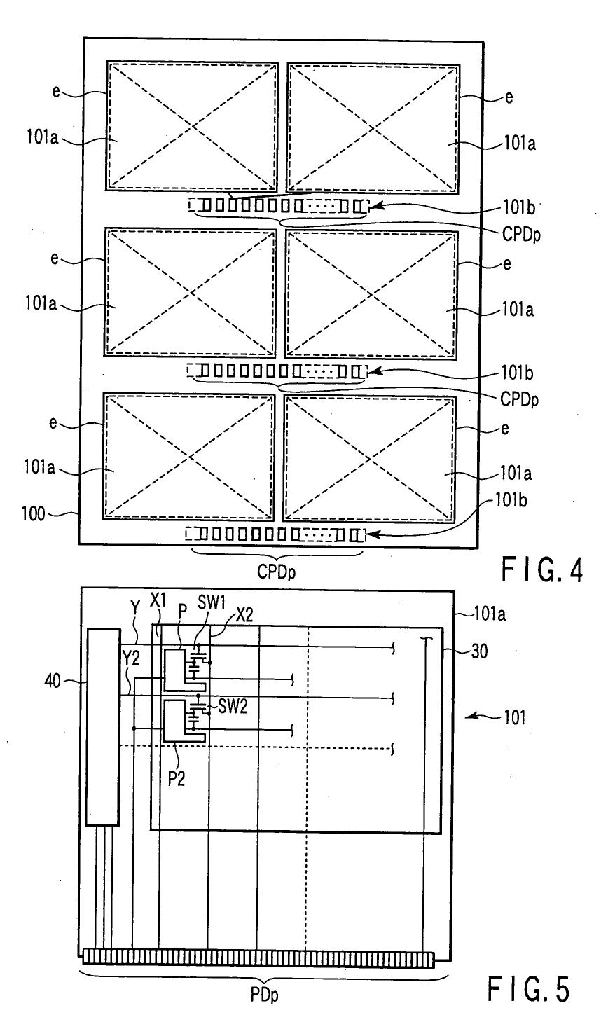

Next, with reference to FIG. 4, the array substrate 101a will be explained. FIG. 4 shows a mother substrate 100 that serves as a substrate having larger dimensions than those of the array substrate 101a, and the figure illustrates an example in which six array substrates 101a are structured with use of the mother substrate. In this manner, array substrates 101a are formed generally with use of the mother substrate 100. The array substrates 101a are formed in the first array region to the sixth array region of the mother substrate 100. An array substrate that is formed but still a part of the mother substrate 100 is called array substrate portion, and when it is separated from the mother substrate 100, it is called array substrate.

Array substrate portions 101a are formed generally with use of the mother substrate 100. Between array substrates 101a, a connection pad group CPDp made of a plurality of terminals is formed. In this embodiment, the common terminal that is a part of the connection pad group CPDp can be short-circuited to both of at least a part of the wiring formed in the first array region and at least a part of the wiring formed in the second array region.

The region in which the connection pad group CPDp is formed is called a sub-pad group region 101b. The array substrate portion 101a and sub-pad group region 101b are unique feature to the present invention, which will be described later in detail.

Respective sides of these array substrate portions 101a are arranged along a cut-off line on the mother substrate 101. Further, each array substrate portion 101a contains, in respective one side, the scanning line drive circuit 40 serving as a drive circuit unit and the normal pad group PDp including a number of terminals connected to signal lines. The normal pad group PDp is used to input different signals through respective terminals, and further to input/output a signal for inspection. The array substrate portions 101a are separated from each other as they are cut off along the edge e after the opposite substrate is adhered in a later step.

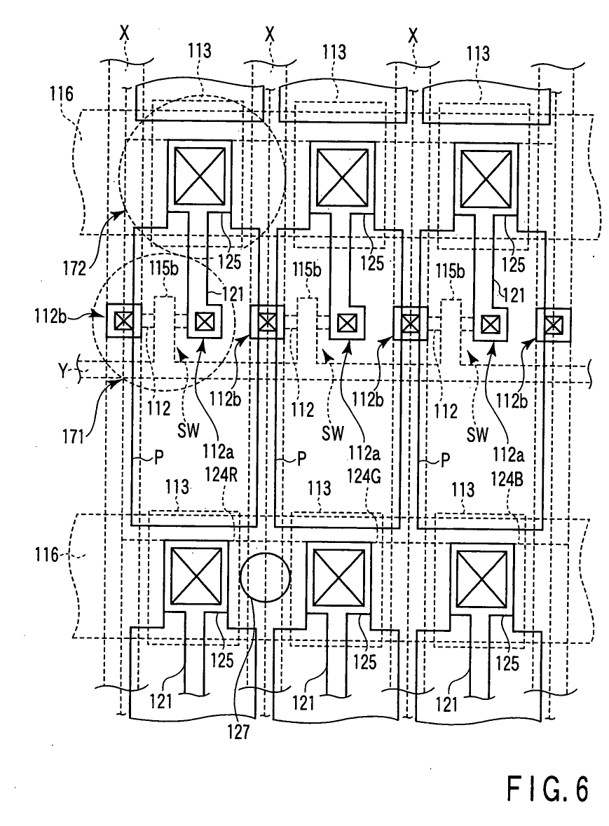

As shown in FIG. 6, on a pixel region 30 on an array substrate 101a, a plurality of pixel electrodes P1, P2, . . . are arranged in matrix. Each array substrate 101a includes, in addition to the pixel electrodes P1, P2, . . . , a plurality of scanning lines Y1, Y2, . . . that are arranged along the columns of the pixel electrodes P1, P2, . . . , and a plurality of signal lines X1, X2, . . . that are arranged along the rows of the pixel electrodes P1, P2, . . . . Further, the array substrate 101a includes thin film transistors (to be called TFT hereinafter) SW1, SW2, . . . serving as switching elements and arranged in a vicinity of each of the intersections of the scanning lines Y1, Y2, . . . and signal lines X1, X2, . . . , and a scanning line drive circuit 40 that drives each of these scanning lines.

When the TFTs SW1, SW2, . . . are driven via the scanning lines Y1, Y2, . . . , respectively, they apply signal voltages of the signal lines X1, X2, . . . to pixel electrodes P. The scanning line drive circuit 40 is placed adjacent to an end portion of the array substrate 101 and in an outer region of the pixel region 30. The scanning line drive circuit 40 is made by utilizing TFT elements that use a polysilicon semiconductor films similar to that of the TFTs SW1, SW2, . . . . In the following descriptions, the signal lines X1, X2, . . . will be called by a general term of signal lines X, and similarly, the scanning lines Y1, Y2, . . . will be scanning lines Y, the pixel electrodes P1, P2, . . . will be pixel electrodes P and the TFTs SW1, SW2, . . . will be TFT elements SW.

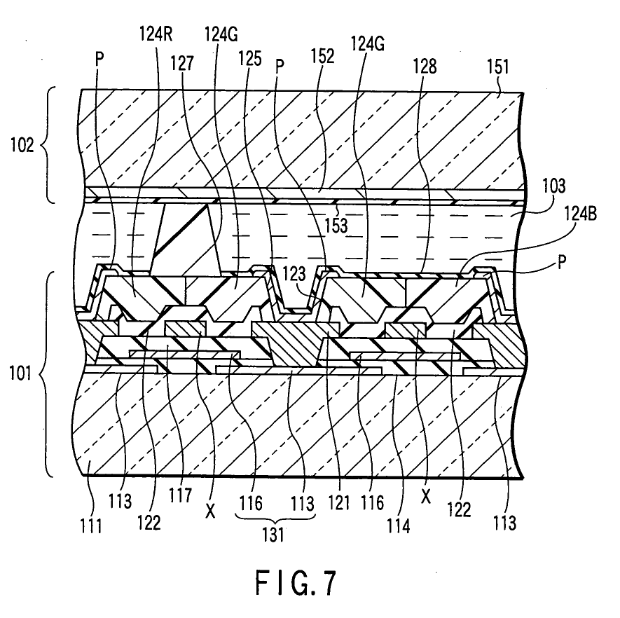

Next, with reference to FIGS. 6 and 7, a part of the pixel region 30 shown in FIG. 5 is focused for further explanation. FIG. 6 is an enlarged plan view schematically showing the pixel region 30 of an array substrate, and FIG. 7 is an enlarged cross sectional view of the pixel region of the liquid crystal display. As shown, the array substrate 101a includes a substrate 111 that is a transparent insulating substrate such as a glass plate. (see FIG. 7) On the substrate 111, a plurality of signal lines X and a plurality of scanning lines Y are arranged in matrix, and a TFT SW is provided in the vicinity of each intersection of a signal line and a scanning line (See the section surrounded by a circle 171 in FIG. 6).

Each TFT SW includes a semiconductor film 112 having source/drain regions 112a and 112b made of polysilicon and a gate electrode 115b, which is an extension of a part of the respective scanning line Y.

On the substrate 111, a plurality of auxiliary capacitor lines 116 are arranged in stripe to form an auxiliary capacitor element 131, and they are extended in parallel with the scanning lines Y. A pixel electrode P is formed in this section. (See FIG. 6, the section surrounded by a circle 172 and FIG. 7.)

In more detail, on the substrate 111, the semiconductor film 112 and auxiliary capacitor lower electrodes 113 are formed, and further, a gate insulating film 114 is formed on the substrate that includes these semiconductor film and auxiliary capacitor lower electrodes. The auxiliary capacitor lower electrodes 113 are formed of polysilicon as in the case of the semiconductor film 112. On the gate insulating film 114, scanning lines Y, gate electrodes 115b and auxiliary capacitor lines 116 are arranged. An auxiliary capacitor line 116 and an auxiliary capacitor lower electrode 113 are arranged to face each other via the gate insulating film 114. An interlayer insulating film 117 is formed on the gate insulating film 114 that includes the scanning lines Y, gate electrodes 115b and the auxiliary capacitor lines 116.

Contact electrodes 121 and signal lines X are formed on the interlayer insulating film 117. Each contact electrode 121 is connected via a respective contact hole to the source/drain region 112a of the respective semiconductor film 112 and the pixel electrode P. The contact electrode 121 is connected to the auxiliary capacitor lower electrode 113. Each signal line X is connected to the source/drain region 112b of the respective semiconductor film 112 via a respective contact hole.

A protective insulating film 122 is formed to overlay on each of the contact electrodes 121, signal lines X and interlayer insulating film 117. On the protective insulating film 112, green coloring layers 124G, red coloring layers 124R and blue coloring layers 124B, which are formed in stripe, are arranged alternately to be adjacent to each other. The coloring layers 124G, 124R and 124B form a color filter.

The pixel electrodes P are formed on their respective coloring layers 124G, 124R and 124B by transparent conductive film such as ITO (indium tin oxide). Each pixel electrode P is connected to the respective contact electrode 121 via a contact hole 125 formed in the coloring layers and protective insulating film 122. The peripheral portion of the pixel electrode P is formed to overlay on an auxiliary capacitor line 116 and signal line X. The auxiliary capacitor element 131 connected to the pixel electrode P functions as auxiliary capacitor store electric charge.

A columnar spacer 127 is formed on the coloring layers 124R and 124G. Although the figure does not show all of them, a plurality of columnar spacers 127 are formed on each of the coloring layers at a predetermined density. An alignment film 128 is formed on the coloring layers 124G, 124R and 124B and the pixel electrodes P. The opposite substrate 102 includes a substrate 151 which is a transparent insulating substrate. An opposite electrode 152 and an alignment film 153, which are made of a transparent material such as ITO, are formed in this order on the substrate 151.

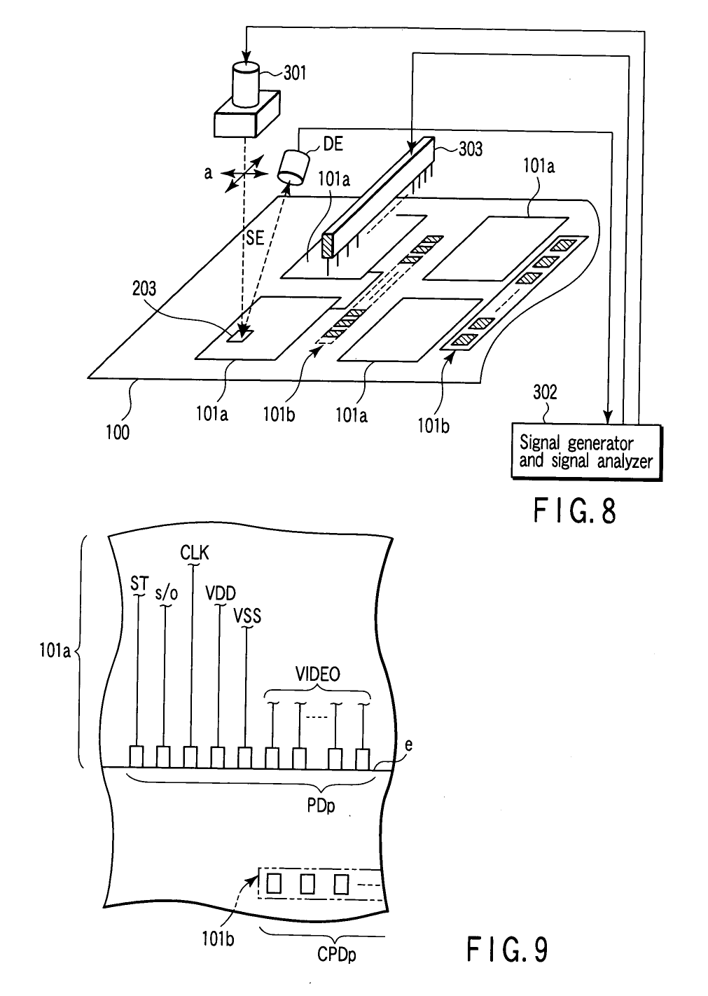

The inspection method for a substrate that includes an array substrate portion 101a, which use an EB tester, will now be described with reference to FIG. 8. It should be noted that a plurality of array substrate portions 101a and a sub-pad group region 101b are formed on the mother substrate 100. The inspection is carried out after forming the pixel electrodes P on the substrate.

First, probes 303 connected to a signal generator and signal analyzer 302 are connected to pads of a corresponding sub-pad group region 101b. Drive signals outputted from the signal generator and signal analyzer 302 are supplied to a pixel section 203 via the probes 303 and pads. After the drive signals are supplied to the pixel section 203, an electron beam EB emitted from an electron beam source 301 is irradiated onto the pixel section. Due to the irradiation, secondary electrons SE are emitted from the pixel section 203, and the secondary electrons SE are detected by an electron detector DE. The secondary electrons SE have correlation to the voltage at the site from where the electrons are emitted. The data of the secondary electrons detected by the electron detector DE are sent to the signal generator and signal analyzer 302 for the purpose of analyzing the pixel section 203. It should be noted here that the change in voltage represents the status pixel section 203. Further, the data of the secondary electrons sent to the signal generator and signal analyzer 302 reflect the performances of each pixel section to the drive signal supplied to the terminal of the TFT element of each pixel section 203. In this manner, it is possible to inspect the state of the voltage at the pixel electrode P of each pixel section 203. In short, if there is a defect in a pixel section 203, the defect can be detected by the EB tester.

The figure illustrates one pixel section 203 as a typical example. With the inspection device, each of the pixel sections of adjacent array substrate portions 101a and 101a can be scanned successively with electron beams. This is because the probes 303 are formed connectable to the common terminals of a plurality of array substrate portions 101a and 101a. The data of the secondary electrons of each pixel section that are obtained as results of the scanning of the electron beams are taken up by the signal generator and signal analyzer 302.

FIG. 9 is an enlarged view of a part of an array substrate portion 101a and illustrates an example of a normal pad group PDp provided in that part. The mother substrate 101 includes the array substrate portion 101a and a sub-pad group region 101b that is located on an outer side of the array substrate portion. It should be noted that after the inspection, an opposite substrate is adhered to the array substrate, and then the sub-pad group region 101b is cut off, for example, along a cut-off line e2.

The normal pad group PDp of the array substrate portion 101a is connected to the scanning line driving circuit 40 and signal lines X shown in FIG. 5 via wiring lines. The types of terminals that form the normal pad group PDp that is located in the array region can be categorized into a logic terminal, a power source terminal, an inspection terminal and a signal input terminal.

The logic terminal includes a terminal CLK and a terminal ST. Signals that are inputted to the terminal CLK and terminal ST are a clock signal and a start pulse signal. The clock signal and start pulse signal are those to be inputted to the scanning line drive circuit 40.

The inspection terminal is a serial output terminal s/o. A signal outputted from the serial output terminal s/o is a serial output signal outputted from a shift register (s/r) of the scanning line drive circuit 40 in reply to the start pulse.

There are a plurality of types of power source terminals such as a terminal VDD and terminal VSS. In this embodiment, the power source terminals can be categorized into two types, namely, terminal VDD and terminal VSS. Signals inputted to the terminal VDD and terminal VSS are a high level power source and low level power source.

The signal input terminal is a terminal VIDEO. An example of the signal to be inputted to the terminal VIDEO is a video signal. It should be noted here that the terminal VIDEO has several hundreds to several thousands terminals and it occupies a large portion of the pad group PDp.

On the other hand, a common connection pad group CPDp is provided in a predetermined position of the sub-pad group region 101b. The common connection pad group CPDp is connected to the normal pad group PDp of the array substrate portion 101a via wiring lines. A significant feature of the present invention is how the common connection pad group CPDp and normal pad group PDp are connected to each other.

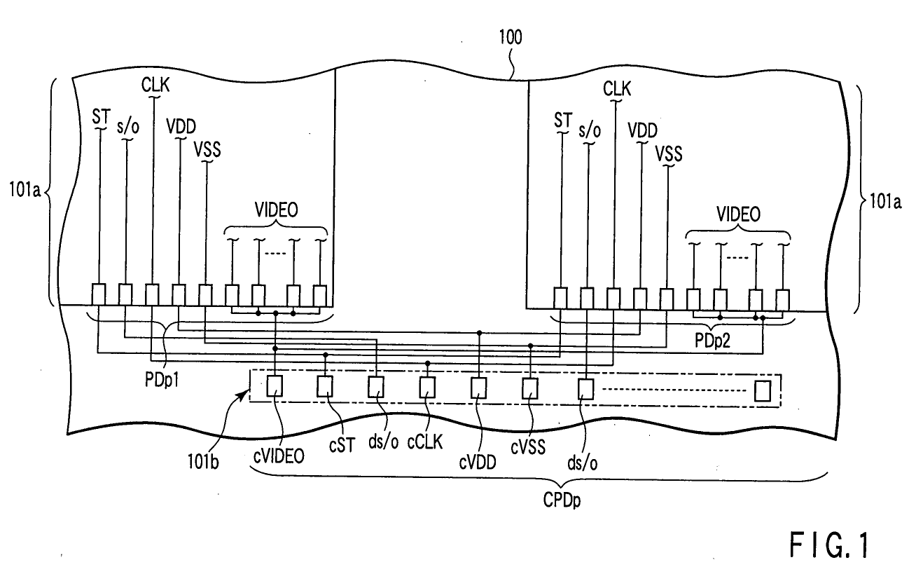

With reference to FIG. 1, an example of the connection relationship between the normal pad group PDp and the common connection pad group CPDp will now be explained. This figure illustrates two array substrate portions 101a and 101a that are arranged on the mother substrate 100, and these array substrate portions include normal pad groups PDp1 and PDp2. The common connection pad group CPDp includes a high-level common terminal cVDD, a low-level common terminal cVSS, a common terminal cCLK, a common terminal cVIDEO, a common terminal cST and a dependent terminal ds/o.

The respective terminals VDD and VSS of the normal pad groups PDp1 and PDp2 are connected to the common terminal cVDD and the common terminal cVSS, respectively. This is because the common high-level power source and low-level power source can be supplied to the terminals VDD and VSS of the normal pad groups PDp1 and PDp2. The terminals CLK of the normal pad groups PDp1 and PDp2 are connected to the common terminal cCLK. The start pulse terminals ST of the normal pad groups PDp1 and PDp2 are connected to the common terminal cST. The VIDEO terminals of the normal pad groups PDp1 and PDp2 are connected to the common terminal cVIDEO. The serial output terminals s/o of the normal pad groups PDp1 and PDp2 are connected to the dependent terminal ds/o.

As described above, with the common connection pad group CPDp, the number of terminals of the connection pad group can be remarkably decreased as compared to the number of terminals in the normal pad groups PDp1 and PDp2.

In addition, in order to connect the normal pad groups PDp1 and PDp2 to the common connection pad groups CPDp, it suffices if a terminal used to supply at least one of electrical signals of the high-level power source, low-level power source, start pulse signal, video signal and clock signal is connected. In other words, when a common input signal can be supplied to terminals of a plurality of array substrate portions 101a, if suffices if a terminal used to supply a common input signal to the common connection pad group CPDp is provided.

The pixel sections of a plurality of array substrate portions 101a having the above-described structure are inspected with an EB tester in the following manner. That is, probes are connected to the terminals of the common connection pad group CPDp, and electrical charges are accumulated on the auxiliary capacitors of the pixel sections 203 via the probes. When each auxiliary capacitor is thus charged, an electron beam is irradiated to each pixel section 203. Then, the secondary electrons emitted from each pixel section are detected, and thus each pixel section 203 is inspected as to whether or not it contains a defect.

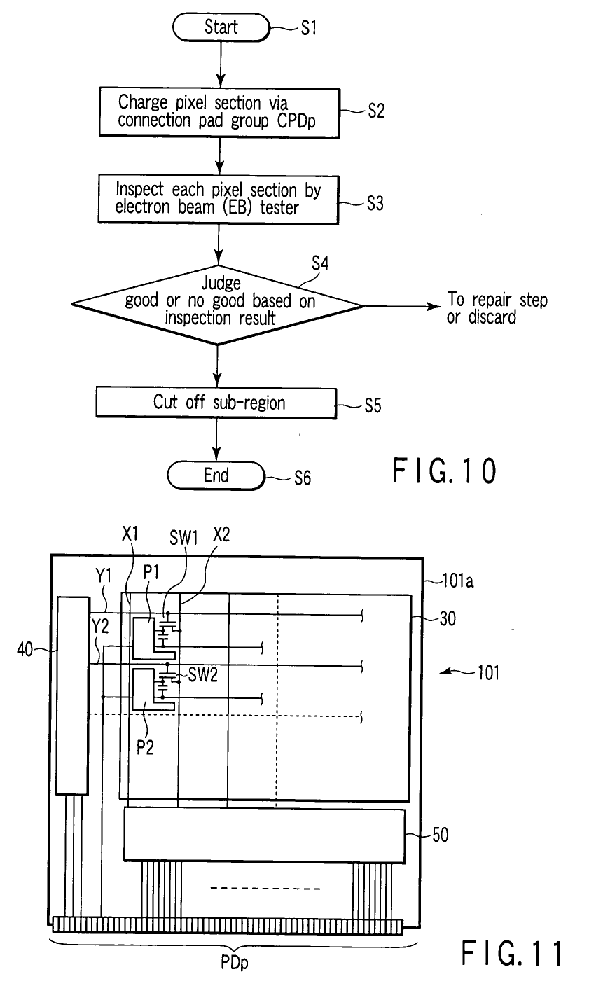

FIG. 10 schematically shows a process of inspecting a substrate that includes a plurality of array substrate portions 101a described above. When the inspection is started (Step S1), the auxiliary capacitors of the pixel sections of the array substrate portions 101a are charged at the same time via the common connection pad group CPDp in a vacuum chamber that is not shown in the figure (Step S2). Then, each pixel section is scanned with the EB tester and the secondary electrons emitted are measured, thereby inspecting each pixel section (Step S3). In the inspection, whether or not the voltage at each pixel section is normal is judged (Step S4). If an array substrate portion with a defect is detected, it is transferred to the repair step or it is discarded. If an array substrate portion is judged to be good, it will be transferred to the next step, where the sub-region described above is cut off (Step S5). Thus, the inspection is completed (Step S6).

With the substrate inspection method and device having the above-described structure, the connection pad group CPDp serving as an inspection pad group is provided in the sub-pad group region 101b. When a common input signal is supplied to terminals of a plurality of array substrate portions 101a, the common input signal is supplied to the terminals via the common connection pad group CPDp. With the common connection pad group CPDp provided in the structure as described above, the number of terminals used for the inspection can be decreased. In this manner, the number of the inspection terminals necessary on one mother substrate 100 can be decreased. Further, in accordance with the decrease in the number of terminals of the connection pad group CPDp, the number of probes of the inspection device can be decreased as well. Consequently, the cost of the inspection device can be reduced while maintaining a good performance of the inspection.

In order to inspect pixel sections 203, a common signal is supplied to two or more array substrate portions 101a at the same time. In this manner, the total time required for the inspection can be shortened. Even if the design of the circuit structure of an array substrate portion 101a is changed, the arrangement structure of the connection pad group CPDp in the sub-pad group region 101b should be maintained in the same pattern. Thus, the change or connection of the design of the inspection device are not necessary. Here, by arranging the mutual relationship in the connection between the inspection device and the array substrate portion 101a and the connection pad group CPDp in various ways, the versatility of the inspection device can be increased. Further, in this manner, the chances of changing or revising of the design of the inspection device can be lowered, and therefore the production cost of the panel can be suppressed from becoming high.

In addition, by performing the inspection of the array substrate portion 101 with use of the EB tester in advance, the defect occurring in a pixel section 203 can be detected. Thus, it is possible to inhibit a product with a defective liquid crystal display from being distributed.

This invention is not limited to the above-described embodiment, but various modifications can be made within the scope of the invention. For example, it is alternatively possible that the position where the connection pad group CPDp is placed is placed is not limited to that of the embodiment provided above, but it may be anywhere as long as it is on the mother substrate 100. It should be noted here that the above-provided explanation of the invention is effectual for the case where a plurality of array substrate portions of different types are formed on a mother substrate 100.

Further, it is only natural that pads for inputting common signals to the array substrates 101a are connected first, and then they are connected to common thermals of a plurality of array substrates 101a.

Furthermore, a scanning line drive circuit 40 and a signal line drive circuit 50 that drives and a plurality of signal lines may be built as a drive circuit unit in the outer region of the pixel region 30 on the array substrate portion 101 as shown in FIG. 11. The signal line drive circuit 50 is made with use of a TFT having a polysilicon semiconductor film as in the case of the TFT SW.

The signal line drive circuit 50 is connected to the connection pad group CPDp via the pad group PDp. With this structure, video signals, which are electrical signals, supplied to the pads of the connection pad group CPCp are distributed from the pads and supplied to different regions in the signal line drive circuit 50. The connection pad group CPDp includes a logic terminal, an inspection terminal, etc. that are connected to the signal line drive circuit 50. When video signals, clock signal and start pulse signal are inputted to the signal line drive circuit 50, a shift register that constitutes the signal line drive circuit 50 is driven and thus an output signal from the shift register is outputted. By analyzing the output, it is judged whether or not the signal line drive circuit 50 is proper.

In the manner described above, the scanning line drive circuit 40 and the signal line drive circuit 50 can be electrically inspected. As the electrical signal is supplied to the scanning line drive circuit 40 and the signal line drive circuit 50 via the connection pad group CPCp, the pixel electrodes P can be electrically charged. Therefore, it is possible to inspect it with electron beams as described above.

As an array substrate 101 to be inspected, it suffices if the substrate includes a drive circuit unit built on the substrate and including at least one of the scanning line drive circuit 40 that supplies drive signals to scanning lines Y and the signal line drive circuit 50 that supplies drive signals to signal lines X. The TFT that constitutes the scanning line drive circuit 40 and the signal line drive circuit 50 may not be of a type using polysilicon.

What is claimed is:

1. A method of inspecting a substrate which comprises a common terminal, and a first array region and a second array region each containing wirings including a plurality of scanning lines and a plurality of signal lines, a plurality of switching elements each formed in a vicinity of an intersection of the respective scanning line and the respective signal line and a plurality of pixel electrodes connected respective to the plurality of switching elements, the method comprising:
forming the common terminal that is connected to a part of wirings formed in the first array region and a part of wirings formed in the second array region on the substrate;
supplying an electric signal from the common terminal to both of the part of the wirings formed in the first array region and the part of the wirings formed in the second array region, thereby charging the pixel electrodes in the first and second array regions; and
irradiating an electron beam to the charged pixel electrodes, and inspecting whether or not the pixel electrodes properly hold the electrical charge based on a data of a secondary electron emitted from the pixel electrodes.

2. The method according to claim 1, wherein the parts of the wirings respectively formed in the first and second array regions include start pulse wirings, and the supplying of the electric signal includes supplying a start pulse signal from the common terminal to the start pulse wirings in the first and second array regions.

3. The method according to claim 1, wherein the parts of the wirings respectively formed in the first and second array regions include clock wirings, and the supplying of the electric signal includes supplying a clock signal from the common terminal to the clock wirings in the first and second array regions.

4. The method according to claim 1, wherein the parts of the wirings respectively formed in the first and second array regions include video wirings, and the supplying of the electric signal includes supplying a video signal from the common terminal to the video wirings in the first and second array regions.

5. The method according to claim 1, wherein the first array region and the second array region each further comprises a drive circuit unit built on the substrate and including a scanning line drive circuit configured to supply a drive signal to each of the scanning lines and a signal line drive circuit configured to supply a drive signal to each of the signal lines.

6. The method according to claim 5, wherein the drive circuit unit and the switching elements each includes a thin film transistor that uses polysilicon.

7. The method according to claim 1, wherein the electric signal is at least one of a power source signal, a start pulse signal, a video signal and a clock signal.
